(19) United States
(12) Patent Application Publication
(10) Pub. No.: US 2026/0247915 A1
(43) Pub. Date: Aug. 20, 2026

(54) STORAGE APPARATUS FOR AUTOMATIC MATERIAL HANDLING SYSTEM

(71) Applicant: NANYA TECHNOLOGY CORPORATION, New Taipei City (TW)

(72) Inventors: Chi Ming Pan, New Taipei City (TW); Po Hsien Chen, New Taipei City (TW); Zheng-Xun Yang, New Taipei City (TW)

(73) Assignee: NANYA TECHNOLOGY CORPORATION, New Taipei City (TW)

(21) Appl. No.: 19/056,787

(22) Filed: Feb. 19, 2025

(51) Int. Cl. H01L 21/677

(52) U.S. Cl. CPC H10P 72/3404; H10P 72/3218; H10P 72/3221

(57) ABSTRACT

A storage apparatus for an automated material handling system, which comprises at least one hanger, a control module, and a crane module. The hanger is installed on a ceiling, has a receiving space and at least two positioning pins in the receiving space. The crane module is disposed under the ceiling and electrically connected to the control module. The hanger is located in an operating range of the crane module, wherein a front opening unified pod (FOUP) is carried by the crane module to be delivered to one of the hanger, a top flange of the FOUP is guided and positioned by the positioning pins so as to be limited in the receiving space, and the FOUP is stored onto the ceiling via the hanger.

### BACKGROUND

### Technical Field

The disclosure is related to a storage apparatus for an automated material handling system.

### Description of Related Art

The semiconductor fabrication plants (commonly referred to as FABs) often use front opening unified pods (FOUPs) to load materials (such as wafers), which are then transported and conveyed through an automatic material handling system (AMHS). Generally speaking, for the structural characteristics of FOUPs, the carriers used for transportation and conveyance are often equipped with positioning pins (KC pins) to provide guidance during the carrying process and to allow the FOUPs to be stably carried on them.

The Overhead Transport (OHT) system can be used for transporting production materials within each production unit, that is, transporting the production materials located in storage cabinets and the production materials/products located in production equipment. A typical OHT system usually relies on rails above the production equipment and operational area, and the platforms or trolleys move along these rails. When the FOUP is used at the load port of production equipment or storage devices (such as storage cabinets or zero footprint buffer, ZFB), interaction with the OHT is still required, so these storage devices can only be set up below the OHT rails.

However, as products become more complex, the number of process steps also increases. Consequently, as the number of production equipment increases, the demand for FOUP storage naturally rises. Large storage devices (such as the aforementioned stocker) can solve storage issues, but they take up space needed for production equipment and are difficult to assemble and disassemble. Moreover, temporary storage areas (ex: ZFBs) are limited by the tracks, which restricts the space and number of these storage areas.

Based on the above, how to provide simple and adjustable storage devices to meet various demands is indeed a topic that needs to be considered by relevant technical personnel.

### SUMMARY

The present disclosure provides a storage apparatus for an automated material handling system. With its simple structure and the characteristic of being detachable and adjustable according to demand, it can effectively utilize ceiling space and achieve flexible scheduling on the production line.

The present disclosure provides a storage apparatus for an automated material handling system, which comprises at least one hanger, a control module, and a crane module. The hanger is installed on a ceiling, has a receiving space and at least two positioning pins in the receiving space. The crane module is disposed under the ceiling and electrically connected to the control module. The hanger is located in an operating range of the crane module, wherein a front opening unified pod (FOUP) is carried by the crane module to be delivered to one of the hanger, a top flange of the FOUP is guided and positioned by the positioning pins so as to be limited in the receiving space, and the FOUP is stored onto the ceiling via the hanger.

The present disclosure provides a storage apparatus for an automated material handling system, which comprises a plurality of suspension brackets, at least one hanger, at least one rail, a control module, and at least one automated guided vehicle (AGV) controlled by the control module to move on the rail. The suspension brackets are vertically and parallelly arranged on a ceiling to form a plurality of hanging spaces, with four adjacent suspension brackets forming one of the hanging spaces. The hanger is supported by the four suspension brackets and located at a bottom of the hanging space. The rail is installed on the suspension brackets and located in the hanging space. The AGV is equipped with a telescopic portion and a gripper, both controlled by the control module to grip and move the hanger in or out of the bottom of the hanging space, wherein the hanger moved out of the bottom is carried by the AGV to move among the suspension brackets.

Based on the above, the storage apparatus for the automated material handling system provides hangers installed on the ceiling, located within the operating range of the lifting module. The hangers have a receiving space and at least two positioning pins therein. Accordingly, when the FOUP is driven by the lifting module, it can move the top flange of the FOUP into the receiving space of the hanger and be positioned by the positioning pins, and allowing the FOUP to be suspended from the ceiling via the hanger, thereby providing additional storage space for the automated material handling system.

On the other hand, another storage apparatus of the automated material handling system uses multiple suspension brackets that are vertically and parallelly arranged on the ceiling to form multiple hanging spaces, with four adjacent suspension brackets forming one hanging space. Additionally, tracks are set up on these suspension brackets, along with an automated guided vehicle. The hanger is supported between the four suspension brackets and is located below the tracks, allowing the gripper of the automated guided vehicle to move the hanger in or out of a bottom pf the hanging space. The hanger, when moved out of the bottom layer, is suitable to be carried by the automated guided vehicle among the suspension brackets, thereby achieving the purpose of transportation. Consequently, when the FOUP is mounted on the hanger, it can be smoothly moved by the drive of the automated guided vehicle. More importantly, these hanging spaces provide additional storage space for the automated material handling system.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of the automated material handling system according to an embodiment of the present disclosure.

FIG. 2 is a top view of the storage apparatus shown in FIG. 1.

FIG. 3 is a schematic diagram showing the FOUP and the hanger separated.

FIG. 4 is a schematic diagram of the assembly or disassembly of the FOUP and the hanger.

FIG. 5 is a schematic diagram showing the wobbling of the FOUP relative to the hanger.

FIG. 6 is an electrical connection relationship diagram of the components of the storage apparatus.

FIG. 7 is a partial side view of the storage apparatus.

FIG. 8 is a schematic diagram of another embodiment of the automated material handling system according to the present disclosure.

FIG. 9 is a top view of the storage apparatus shown in FIG. 8.

FIG. 10 is a partial top view of FIG. 9.

FIG. 11 is a partial side view of the storage apparatus shown in FIG. 8.

FIG. 12 is a schematic diagram of another embodiment of the automated material handling system according to the present disclosure.

FIG. 13 is a partial top view of FIG. 12.

FIG. 14 is a schematic diagram of another embodiment of the automated material handling system according to the present disclosure.

### DESCRIPTION OF THE EMBODIMENTS

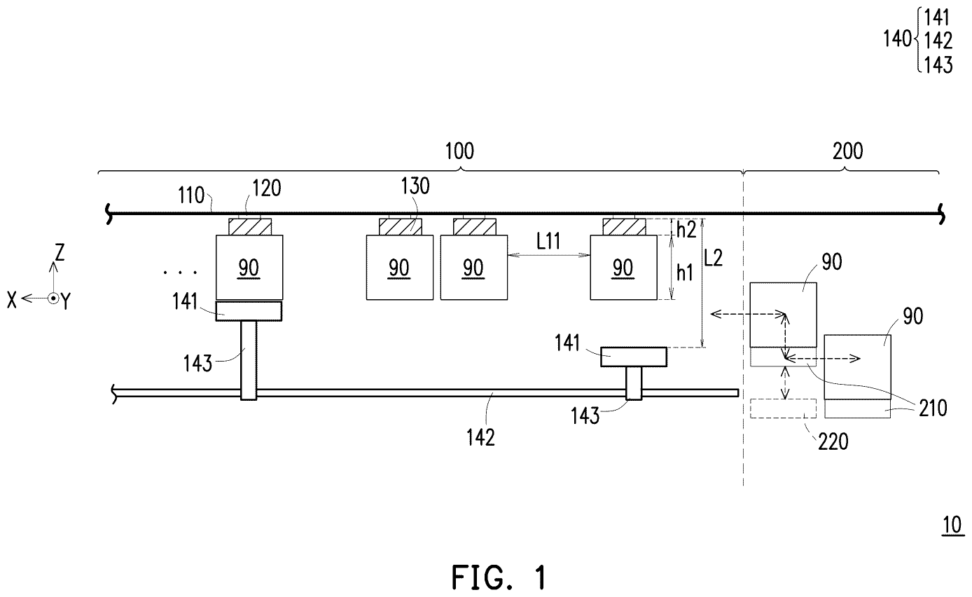

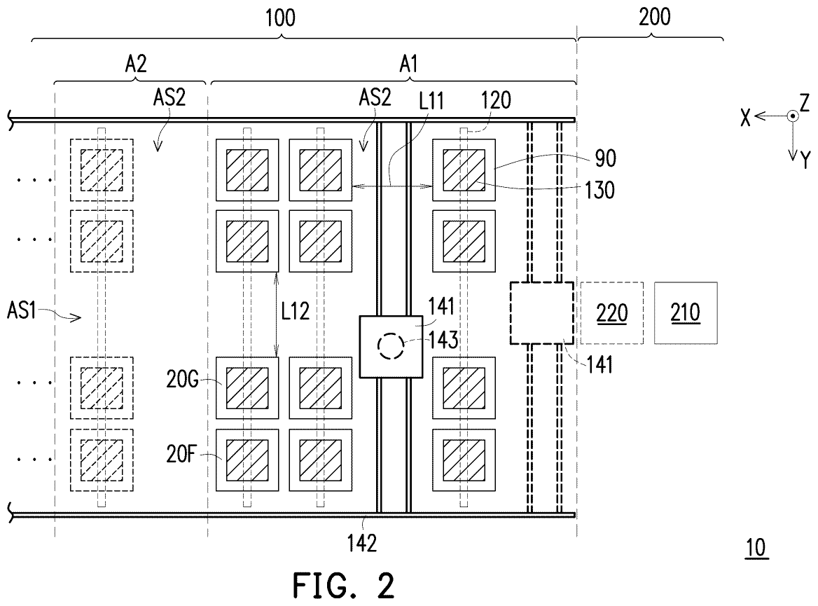

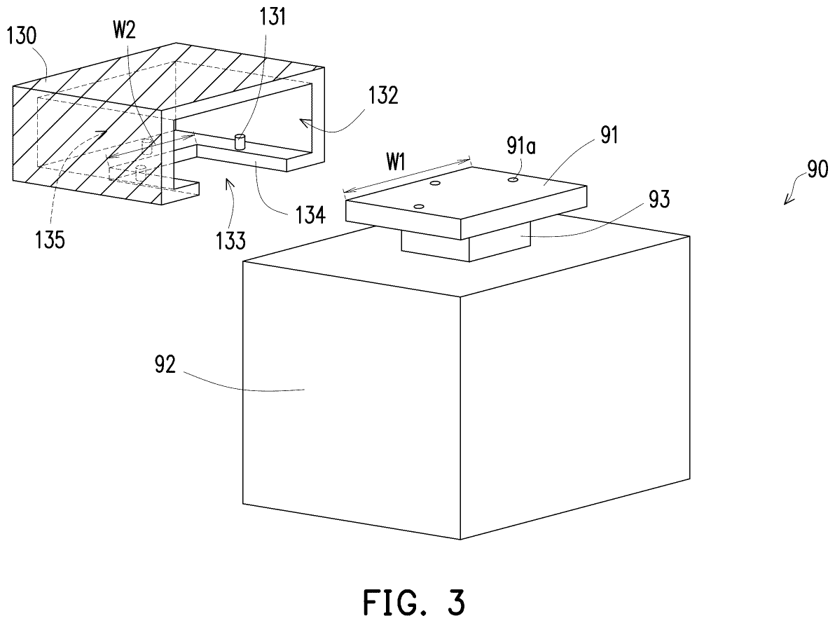

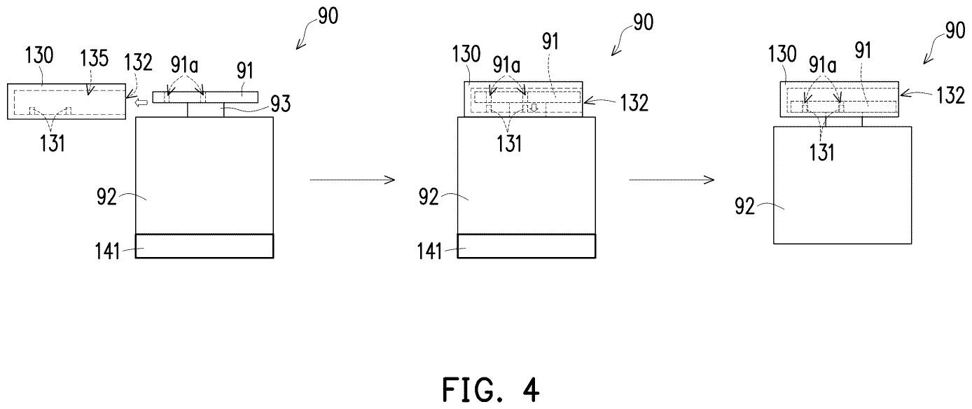

FIG. 1 is a schematic diagram of the automated material handling system according to an embodiment of the present disclosure. FIG. 2 is a top view of the storage apparatus shown in F IG. 1. Please refer to FIG. 1 and FIG. 2 simultaneously, in this embodiment, an automated material handling system (AMHS) 10 includes a storage apparatus 100 and a transporting apparatus 200. The storage apparatus 100 includes at least one hanger 130 (a plurality of hangers 130 are shown in the present embodiment) and a crane module 140. The hanger 130 is installed on a ceiling 110. In fact, there are multiple beams 120 set on the ceiling 110, and each of the hangers 130 is assembled to the beam 120 or detached from the beam 120. In thi embodiment, a Cartesian coordinate system X-Y-Z is provided in the diagrams, where the hangers 130 on the ceiling 110 are located on the X-Y plane. The crane module 140 has three-axis driving dimensions to carry and drive the front opening unified pod (FOUP) 90 towards the corresponding hanger 130, assembled to the hanger 130, or detach and leave the FOUP 90 from the hanger 130.
FIG. 3 is a schematic diagram showing the FOUP and the hanger separated. FIG. 4 is a schematic diagram of the assembly or disassembly of the FOUP and the hanger. Please refer to FIG. 3 and FIG. 4 simultaneously, in this embodiment, the crane module 140 is disposed under the ceiling 110 and the hangers 130, and the hangers 130 are located in an operating range of the crane module 140, wherein the FOUP 90 is carried by the crane module 140 to be delivered to one of the hanger 130, a top flange 91 of the FOUP 90 is guided and positioned by positioning pins 131 so as to be limited in the receiving space 135 of the hanger 130, and the FOUP 90 is stored onto the ceiling 110 via the hanger 130.

As shown in FIG. 1 and FIG. 2, the crane module 140 includes a main bracket 142 in “H” type, a middle beam of the main bracket 142 is movable relative to two side beams of the main bracket 142, and a carrier 141 is movable relative to the middle beam, such that the movement above is located on the X-Y plane. The FOUP 90 is supported on the carrier 141 of the crane module 140 to move on the X-Y plane along with the carrier 141. Besides, the crane module 140 further has lifting mechanism 143 connected between the carrier 141 and the main bracket 142 so as to lift up or lower down the FOUP 90 in Z-axis.

Please refer to FIG. 3 and FIG. 4, the hanger 130 installed on a ceiling 110 has the receiving space 135, a bottom slot 133, a lateral opening 132, and three positioning pins 131 located on a protruding edge 134 of the hanger 130 along the bottom slot 133. The top flange 91 of the FOUP 90 moves in or out of the receiving space 135 by passing through the lateral opening 132, and a neck portion 93 of the FOUP 90 moves in or out of the bottom slot 133 along with the top flange 91 moving, wherein the neck portion 93 is connected between a pod body 92 and the top flange 91 of the FOUP 90. As shown in FIG. 4, according to the movement of the crane module 140, the FOUP 90 firstly moves upward (in positive Z-axis direction) to a position corresponding to the lateral opening 132, wherein the top flange 91 is higher than the three positioning pins 131. Secondary, the crane module 140 drives the FOUP 90 to move the top flange 91 into the receiving space 135 (in positive X-axis direction) and move the neck portion 93 into the bottom slot 133 until three positioning holes 91a are corresponding to the three position pins 131 respectively. At last, the crane module 140 moves downward (in negative Z-axis direction) to insert the three positioning pins into the three positioning holes, and the FOUP 90 is secured to the hanger 130 after the crane module 140 leaves the FOUP 90. On the other hand, by performing the steps above in reverse, the FOUP 90 can be detached from the hanger 130. In the present embodiment, a top of the positioning pin 131 could be rounded or tilt, so as to provide guiding effect in the insertion of the positioning pin 131 toward the positioning hole 91a.

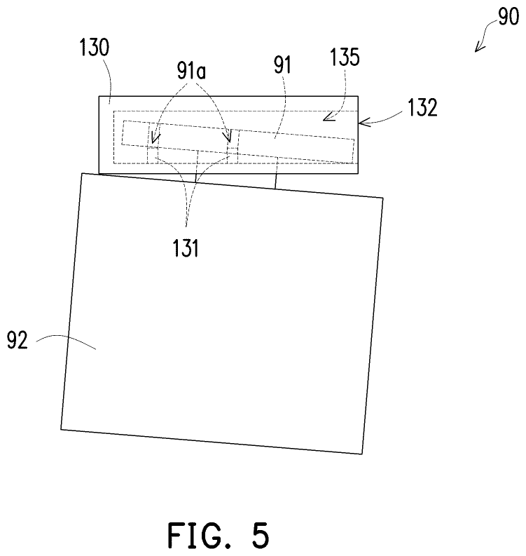

FIG. 5 is a schematic diagram showing the wobbling of the FOUP relative to the hanger. Please refer to FIG. 4 and FIG. 5, in the present embodiment, the lateral opening 132 is the only one entrance or exit for the top flange 91 moving in or out of the receiving space 135, which results in a unique assembly/disassembly path of the FOUP 90 and hanger 130, thereby causing the hanger 130 to impose multi-dimensional restrictions on the top flange 91 of the FOUP 90. At the same time, the size of the receiving space 135 along the Z-axis is further limited so as to prevent the top flange 91 from easily detached from the hanger 130. As shown in FIG. 5, when wobbling or shaking occurs due to an earthquake, the hanger 130 provides blocking for the FOUP 90 due to the above conditions, thereby preventing the FOUP 90 from falling.

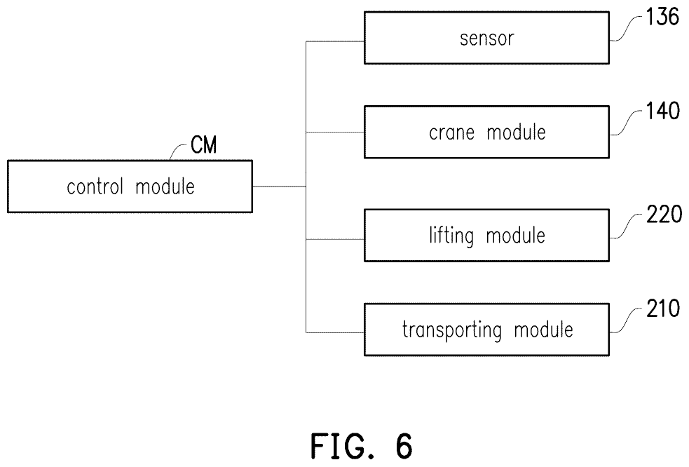

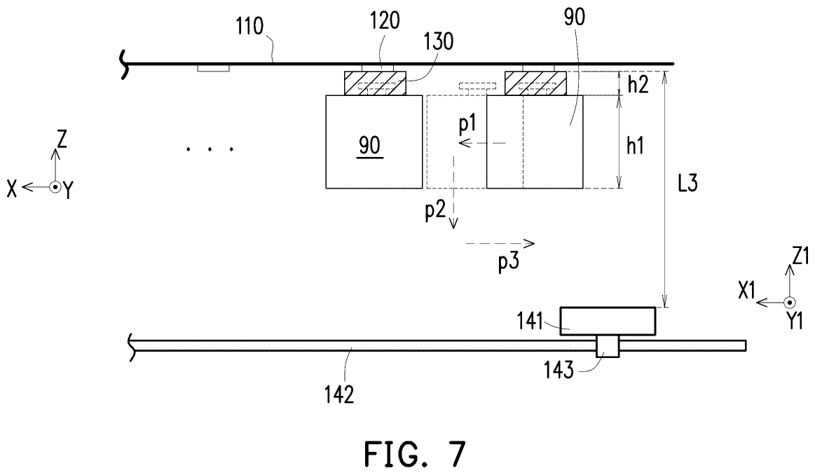

FIG. 6 is an electrical connection relationship diagram of the components of the storage apparatus. FIG. 7 is a partial side view of the storage apparatus. Please refer to FIG. 1, FIG. 6, and FIG. 7, in the present embodiment, the storage apparatus 100 further includes a control module CM electrically connected to the crane module 140, the transporting apparatus 200 comprises a conveying module 210 and a lifting module 220, electrically connected to the control module CM respectively. As shown in FIG. 1 and FIG. 2, the FOUP 90 could be transported to the crane module 140 by the conveying module 210 and the lifting module 220 of the transporting apparatus 200. Besides, there are several sensors disposed in the hangers 130 respectively and electrically connected to the control module CM, such that whether the FOUP 90 is located and secured to the hanger 130 could be known by a control center or a user for better scheduling. The control module CM, which is an electronic assembly including a controller, a processor and a storage unit.

Please refer to FIG. 2, it also shows a configuration of the hangers 130 and the FOUPs 90 therewith. In the present embodiment, the hangers 130 are arranged in an array on the X-Y plane, such that each hanger 130 faces a first aisle AS1 extending along an X-axis, a second aisle AS2 extending along a Y-axis, or both of the first aisle AS1 and the second aisle AS2. In order to pass the FOUP 90 smoothly, a width L11 of the first aisle AS1 and a width L12 of the second aisle AS2 are each greater than or equal to a width W3 of the FOUP 90, such that after the FOUP 90 detached from the hanger 130, the FOUP 90 could be moved on the X-Y plane by the crane module 140. That is to say, the FOUP 90 moved away from the hanger 130 can still move between other FOUPs 90 in the same layer with other hangers 130.

Please refer to FIG. 7, another movement mode is provided therein, the operating range of the crane module 140 in FIG. 7 comprises a two-dimension plane parallel to the X-Y plane and under the hangers 130. Another Cartesian coordinate system X1-Y1-Z1 is provided in FIG. 7, and the two-dimension plane is the X1-Y1 plane. The crane module 140 in FIG. 7 has more space for moving, especially in Z-axis, such that the FOUP 90 moves in paths p1, p2, and p3 sequentially after detached from the hanger 130. In the present embodiment, an operating height L3 of the crane module 140 (on X1-Y1 plane) is greater than or equal to twice a sum of a height h1 of the FOUP 90 and a height h2 of the hanger 130, a width of the first aisle AS1 and a width of the second aisle AS2 are each less than a width of the FOUP 90 and greater than a width of the hanger 130.

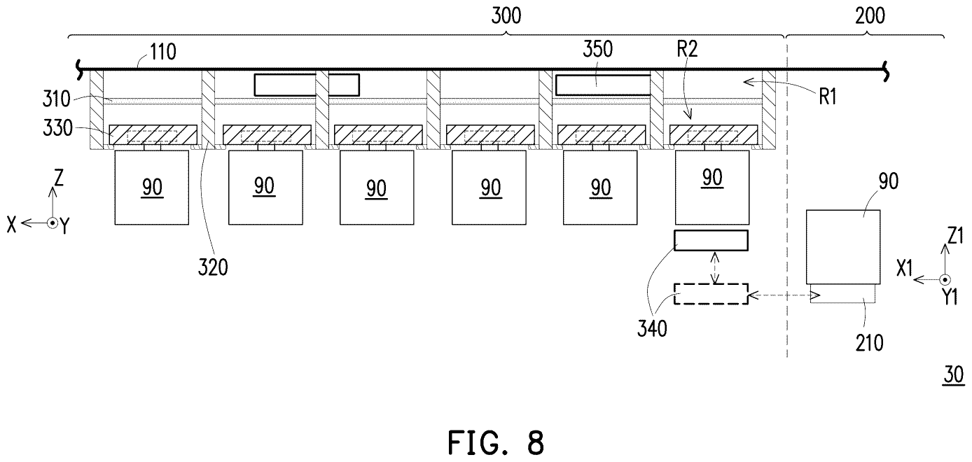

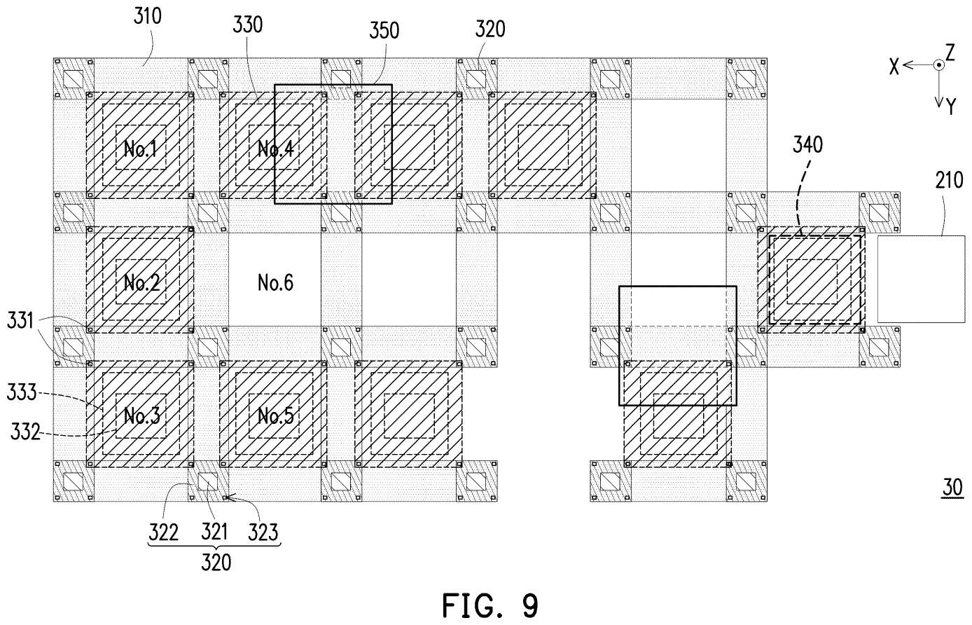

FIG. 8 is a schematic diagram of another embodiment of the automated material handling system according to the present disclosure. FIG. 9 is a top view of the storage apparatus shown in FIG. 8. Please refer to FIG. 8 and FIG. 9, in the present embodiment, the AMHS 30 includes a storage apparatus 300 and a transporting apparatus 200, wherein the composition of the transporting apparatus 200 is the same as the previous embodiment, so no further description will be given. The storage apparatus 300 includes a plurality of suspension brackets 320, hangers 130, rail 310, and an automated guided vehicle (AGV) 350 controlled by a control module (which is not shown here, please refer to previous embodiment) to move on the rail 310. The suspension brackets 320 are vertically and parallelly arranged on a ceiling 110 to form a plurality of hanging spaces R2, with four adjacent suspension brackets 320 forming one of the hanging spaces R2. The hanger 130 is supported by the four suspension brackets 320 and located at a bottom of the hanging space R2. The rail 310 is installed on the suspension brackets 320 and located in the hanging space R2. Besides, the storage apparatus 300 further comprises a crane module 340, the same as the crane module 140 in the previous embodiment, disposed under the suspension brackets 320 and facing toward one of the hanging spaces R2, a FOUP 90 is carried by the crane module 340 to be delivered and secured to the hanger 330, wherein the crane module 340 has three-axis movement dimensions.

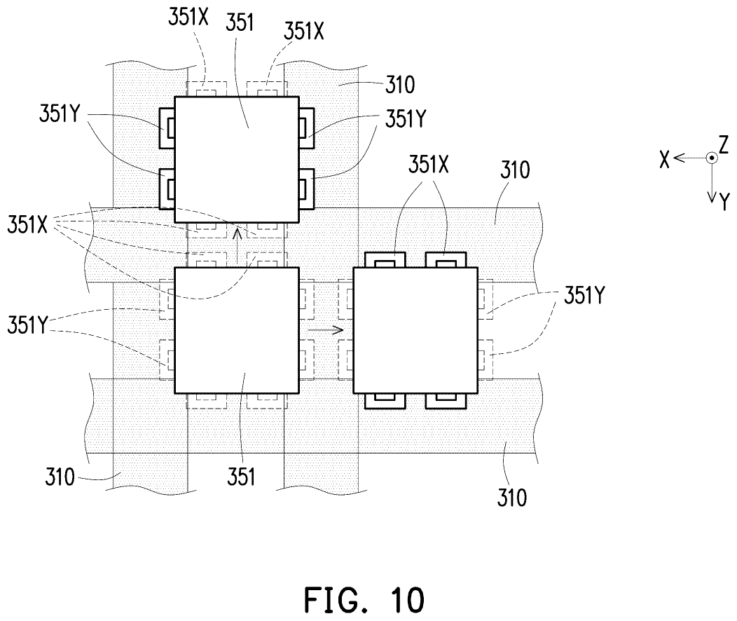

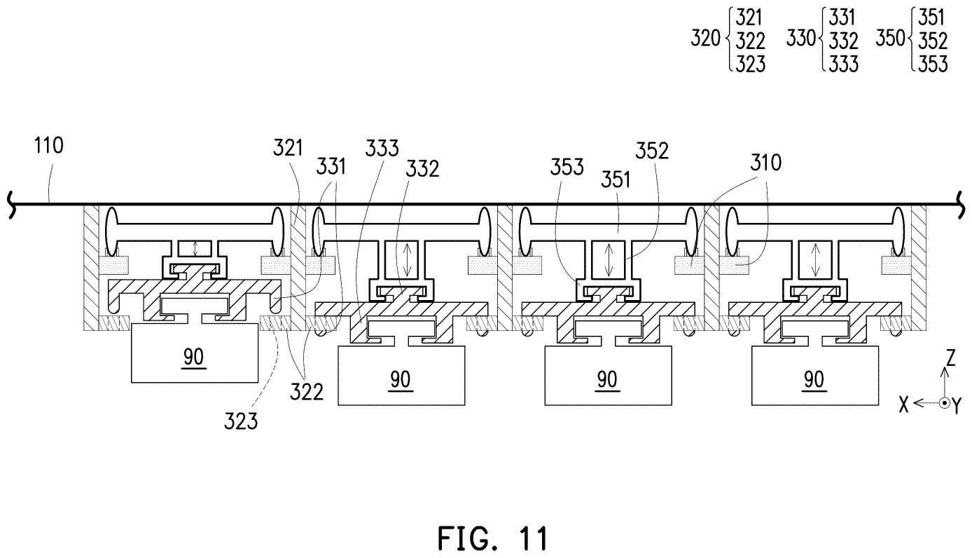

FIG. 10 is a partial top view of FIG. 9. FIG. 11 is a partial side view of the storage apparatus shown in FIG. 8. Please refer to FIG. 8, FIG. 9, and FIG. 11, the AGV 350 is equipped with a telescopic and rotating portion 352 and a gripper 353, both controlled by the control module to grip and move the hanger 130 in or out of the bottom of the hanging space R2, wherein the hanger 130 moved out of the bottom is carried by the AGV 350 to move among the suspension brackets 320.

More specifically, please refer to FIG. 8, FIG. 10, and FIG. 11, the suspension bracket 320 comprises a hanging rod 321 and at least one support frame 322, one end of the hanging rod 321 is assembled to the ceiling 110, and the support frame 322 is installed on the other end of the hanging rod 321, the support frame 322 has multiple slots 323 corresponding to different hanging spaces R2, a plurality of tenons 331 of the hanger 330 are set at multiple corners of the hanger 330, with the tenons 331 each correspondingly embedded into one of the slot 323 of the support frame 322 to secure the hanger 330 at the bottom of the hanging space R2. On the other hand, once the hanger 330 is gripped by the gripper 353 of the AGV 350 to leave the support frames 322, the hanger 330 and the FOUP 90 thereon are carried and moved by the AGV 350.

In the present embodiment, the hanger 330 is similar to the hanger 130 of previous embodiment, and the difference between two embodiments is that the hanger 330 further has the tenons on four corners of a main body 333 and a top flange 332 for the gripper 353 of the AGV 350. That's to say, the main body 333 of the hanger 330 is substantially the same as the hanger 130 for securing the FOUP 90. Therefore, please refer to the foregoing embodiment for the same structure and will not be described again here.

Please refer to FIG. 9 to FIG. 11 again, the AGV 350 in the present embodiment has a vehicle body 351 in rectangular shape from top view and a plurality of wheels 351X, 351Y arranged on four side edges of the vehicle body 351. According to array characteristics in FIG. 9, the rail 310, the suspension brackets 320, the hanging spaces R2, and the hanger 330 in the hanging space R2 are arranged in an array on the X-Y plane. Therefore, the driving mode of the AGV 350 is to travel along the X-axis or along the Y-axis. Accordingly, the wheels 350X of the AGV 350 are used to drive the vehicle body 351 to move along the X-axis on the rail 310. At the same time, the wheels 350Y are retracted and do not operated (not in contact with the rail 310). On the other hand, the wheels 350Y of the AGV 350 are used to drive the vehicle body 351 to move along the Y-axis on the rail 310, and the wheels 350X are retracted and do not operated (not in contact with the rail 310). In FIG. 10, the wheels 350X, 350Y are shown in solid lines when they are operated and in dash lines when they are not.

As shown in FIG. 9, since the hangers 330 can be moved to a specific position by the AGV 350 to load the FOUP 90 and then transported to any empty space for storage, and vice versa for retrieving the FOUP 90, this embodiment allows for more flexible storage space without restrictions on space, storage, or movement paths. The operator can freely adjust the number of storage locations and, with algorithmic planning, can flexibly allocate storage positions and paths. For example, in FIG. 9, for hangers 330 with NO.1, NO.2, NO.3, NO.4, and NO.5, since the NO.1 and NO.3 hangers 330 are limited (or blocked) by surrounding hangers 330, obstacles can be temporarily moved to another location to create an empty space, such as a vacancy with NO.6. Then, the NO.1, NO. 2, and NO.4 hangers 330 can be moved in counterclockwise, i.e., the NO.2 hanger 330 is moved to the right, the NO.1 hanger 330 is moved down, and the NO.4 hanger 330 is moved to the left, and then by performing these movements again in a counterclockwise, finally the NO.1 hanger 330 can be moved to the NO.6 vacancy, such that the NO.1 hanger 330 can be smoothly moved out of the original position.

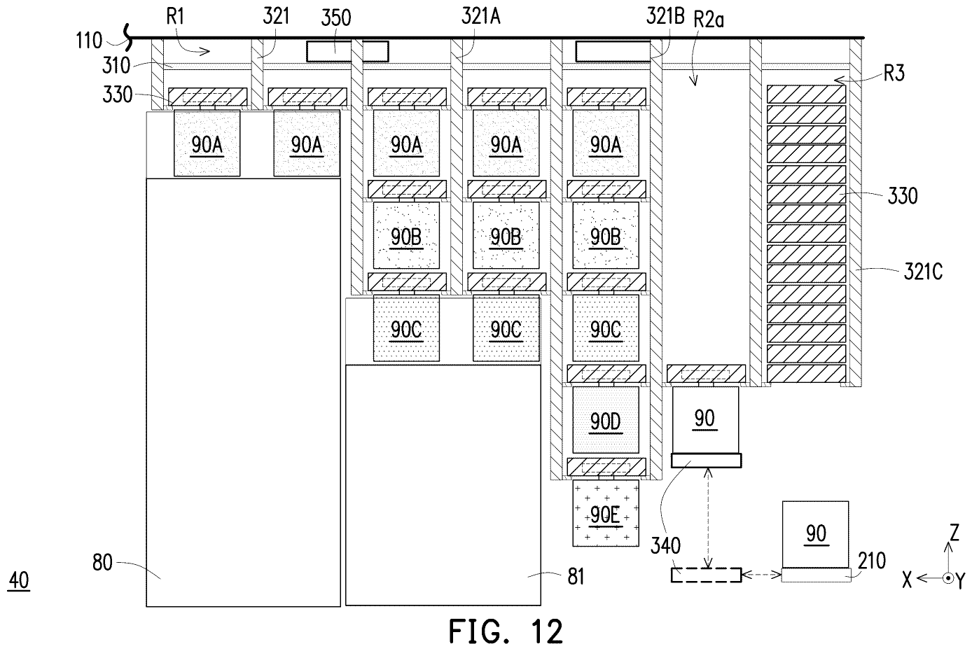

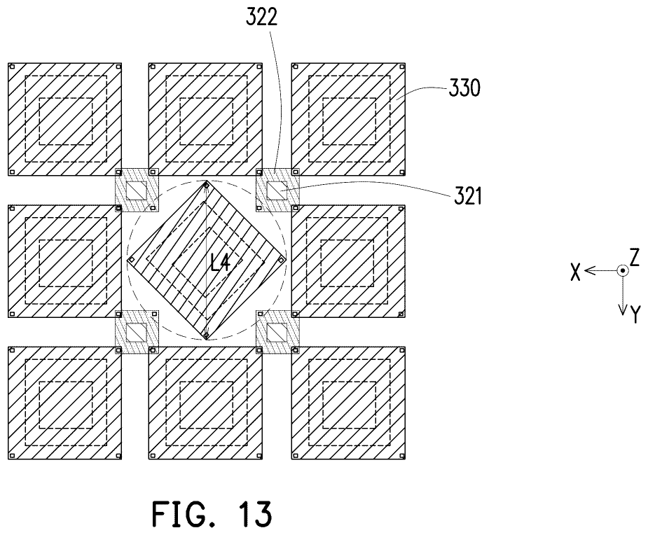

FIG. 12 is a schematic diagram of another embodiment of the automated material handling system according to the present disclosure. Please refer to the AMHS 40 in FIG. 12, there are hanging rods 321, 321A, 321B, 321C in different lengths, wherein the hanging rods 321A, 321B are each paired with different numbers of support frames 322. These support frames 322 are layered on the hanging rod 321A, 321B to create different levels of the hanging space R2. The length of these hanging rods 321, 321A, 321B is adjusted according to the required number of layers. A transporting tunnel R1 formed by the AGV 350 and the corresponding rail 310 are disposed on top of the layers. FIG. 13 is a partial top view of FIG. 12. Please refer to FIG. 12, FIG. 13, and compare to FIG. 11, in the present embodiment, the telescopic and rotating portion 352 of the AGV 350 further rotates the hanger 330 in the hanging space R2 when the gripper 353 grips the hanger 330, and an orthogonal projection of the hanging space R2 on the ceiling 110 (it can also be regarded as an orthographic projection on the X-Y plane) is greater than or equal to a rotation radius of the hanger 330 in the hanging space R2, wherein the rotation radius is half of the diagonal line L4 of the hanger 330. It also means that half of the diagonal line L4 of the orthogonal projection of the hanger 330 on the ceiling 110 forms a radius of rotation when the hanger 330 rotates in the hanging space R2, and an orthogonal projection of the hanging space R2 on the ceiling 110 is greater than or equal to the radius of rotation.

Since the number of hangers 330 and the FOUPs 90 suspended on them can be adjusted according to needs, this means that the space utilization rate of the FAB area is improved. As shown in FIG. 12, production equipment 80 and 81 can be installed below some of the FOUPs 90A, 90B, and 90C. Besides, another hanging space R3 in FIG. 12 is used for storing multiple hangers 330 stacking on top of each other, and a transporting tunnel R2a in FIG. 12 serves as a space for exchanging FOUP 90 between the AGV 350 and the crane module 340. The transporting tunnel R1 communicated with the transporting tunnel R2a and the hanging space R3 to improve the entire AMHS 40.

In FIG. 12, the arrangement of the FOUP 90 in the space can be adjusted according to demand and is divided into hot zone storage and non-hot zone storage based on usage requirements. For example, the FOUPs 90A are in the hot zone storage, which is closer to the AGV 350 than others, allowing for faster retrieval and placement. Sequentially, the FOUPs 90B, 90C, 90D, and 90E successively decrease in retrieval and placement priority, resulting in longer retrieval and placement times (or may require moving other FOUPs in the retrieval and placement path first).

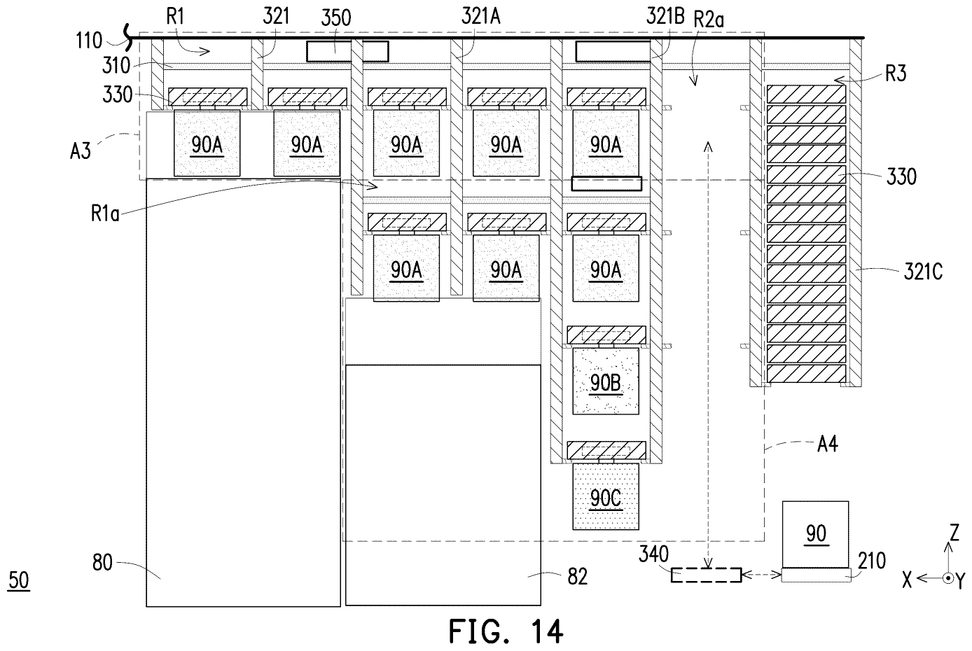

FIG. 14 is a schematic diagram of another embodiment of the automated material handling system according to the present disclosure. Please refer to FIG. 14 and compare to FIG. 12, wherein the difference is that the AMHS 50 comprises a plurality of rails 310 and a plurality AGVs 350 corresponding to each other, wherein the hanging rods 321, 321A, 321B and the support frames 322 form multiple layer spaces, and the AGVs 350 are arranged in different layer spaces with corresponding rail 310. In FIG. 14, there are two transporting tunnels R1, R1a for two AGVs 350. In other words, there will be two layers of FOUPs 90A are in the hot zone so as to increase the classification of the storage areas. At the same time, comparing FIG. 11 and FIG. 12, It can also shows that the AMHS 40, 50 in the present disclosure can also be modularized with different storage compositions according to needs. For example, there are two storage module A3, A4 shown in FIG. 14, different modules A3, A4 can be stacked or combined with each other when configured according to need, such that the storage capacity could be maximized and the pick-and-place efficiency could be optimized. Furthermore, since at least a part of the hanging spaces R2 of these different modules A3 and A4 can be communicated with each other, the AGV 350 can also perform cross-area (across different modules) FOUPs pick-and-place operations for the same hanging space R2. For example, when the AGV 350 at lower layer (in the transporting tunnel R1a) leaves the hanging space R2 formed by the hanging rod 321B, then the AGV 350 at higher layer (in the transporting tunnel R1) could pick and place the FOUPs 90A, 90B, and 90C.

Based on above, the storage apparatus for the automated material handling system provides hangers installed on the ceiling, located within the operating range of the lifting module. The hangers have a receiving space and at least two positioning pins therein. Accordingly, when the FOUP is driven by the lifting module, it can move the top flange of the FOUP into the receiving space of the hanger and be positioned by the positioning pins, and allowing the FOUP to be suspended from the ceiling via the hanger, thereby providing additional storage space for the automated material handling system.

On the other hand, another storage apparatus of the automated material handling system uses multiple suspension brackets that are vertically and parallelly arranged on the ceiling to form multiple hanging spaces, with four adjacent suspension brackets forming one hanging space. Additionally, tracks are set up on these suspension brackets, along with an automated guided vehicle. The hanger is supported between the four suspension brackets and is located below the tracks, allowing the gripper of the automated guided vehicle to move the hanger in or out of a bottom pf the hanging space. The hanger, when moved out of the bottom layer, is suitable to be carried by the automated guided vehicle among the suspension brackets, thereby achieving the purpose of transportation. Consequently, when the FOUP is mounted on the hanger, it can be smoothly moved by the drive of the automated guided vehicle. More importantly, these hanging spaces provide additional storage space for the automated material handling system.

The assembly structure of the above-mentioned AMHS can be adjusted according to needs. Those equipped with AGV can also classify and modularize the storage according to the types of FOUPs or the pick-and-place priority, so that modules of different structures can be stacked and combined with each other, thereby maximizing the storage capacity and optimizing the pick-and-place efficiency of the entire AMHS.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A storage apparatus for automatic material handling system, comprising:
at least one hanger, installed on a ceiling, having a receiving space and at least two positioning pins in the receiving space;
a control module; and
a crane module, disposed under the ceiling, electrically connected to the control module,
wherein the hanger is located in an operating range of the crane module,
wherein a front opening unified pod (FOUP) is carried by the crane module to be delivered to the hanger, a top flange of the FOUP is guided and positioned by the positioning pins so as to be limited in the receiving space, and the FOUP is stored onto the ceiling via the hanger.

2. The storage apparatus for automatic material handling system of claim 1, wherein the hanger has a lateral opening and a bottom slot, the positioning pins are located on a protrusion of the hanger along an edge of the bottom slot, the top flange of the FOUP moves in or out of the receiving space by passing through the lateral opening, and a neck portion of the FOUP moves in or out of the bottom slot along with the top flange moving, wherein the neck portion is connected between a pod body and the top flange.

3. The storage apparatus for automatic material handling system of claim 2, wherein the lateral opening is the only one entrance or exit for the top flange moving in or out of the receiving space.

4. The storage apparatus for automatic material handling system of claim 2, wherein a width of the bottom slot is smaller than a width of the top flange.

5. The storage apparatus for automatic material handling system of claim 1, wherein the crane module has three-axis movement dimensions.

6. The storage apparatus for automatic material handling system of claim 1, wherein there exist a plurality beams on the ceiling, and the at least one hanger is assembled to or detached from the beam.

7. The storage apparatus for automatic material handling system of claim 1, comprising a plurality of hangers, arranged in an array on a X-Y plane, each hanger facing a first aisle extending along an X-axis, a second aisle extending along a Y-axis, or both of the first and the second aisles.

8. The storage apparatus for automatic material handling system of claim 7, wherein a width of the first aisle and a width of the second aisle are each greater than or equal to a width of the FOUP.

9. The storage apparatus for automatic material handling system of claim 7, wherein the operating range of the crane module comprises a two-dimension plane parallel to the X-Y plane and under the hangers.

10. The storage apparatus for automatic material handling system of claim 9, wherein an operating height of the crane module is greater than or equal to twice a sum of a height of the FOUP and a height of the hanger, a width of the first aisle and a width of the second aisle are each less than a width of the FOUP and greater than a width of the hanger.

11. A storage apparatus for automatic material handling system, comprising:
a plurality of suspension brackets, vertically and parallelly arranged on a ceiling to form a plurality of hanging spaces, with four adjacent suspension brackets forming one of the hanging spaces;
at least one hanger, supported by the four adjacent suspension brackets and located at a bottom of the hanging space;
at least one rail, installed on the suspension brackets and located in the hanging space;
a control module; and
at least one automated guided vehicle (AGV), controlled by the control module to move on the rail, wherein the AGV is equipped with a telescopic portion and a gripper, both controlled by the control module to grip and move the hanger in or out of the bottom of the hanging space, wherein the hanger moved out of the bottom is carried by the AGV to move among the suspension brackets.

12. The storage apparatus for automatic material handling system of claim 11, wherein the suspension bracket comprises a hanging rod and at least one support frame, one end of the hanging rod is assembled to the ceiling, and the support frame is installed on the other end of the hanging rod, the support frame has multiple slots corresponding to different hanging spaces, a plurality of tenons of the support frame are set at multiple corners of the hanger, with the tenons each correspondingly embedded into one of the slot of the support frame to secure the hanger at the bottom of the hanging space.

13. The storage apparatus for automatic material handling system of claim 12, wherein the suspension bracket includes the hanging rod and a plurality of support frames, and the support frames are arranged on the hanging rod to separate the hanging space in multiple layers.

14. The storage apparatus for automatic material handling system of claim 13, wherein lengths of the hanging rods are adjusted with required layers.

15. The storage apparatus for automatic material handling system of claim 13, wherein the AGV has a rotating portion to drive the hanger to rotate in the hanging space when the gripper grips the hanger, wherein half of the diagonal line of the orthogonal projection of the hanger on the ceiling forms a radius of rotation when the hanger rotates in the hanging space, and an orthogonal projection of the hanging space on the ceiling is greater than or equal to the radius of rotation.

16. The storage apparatus for automatic material handling system of claim 13, further comprises a plurality of rails and a plurality AGVs corresponding to each other, wherein the hanging rods and the support frames form multiple layer spaces, and the AGVs are arranged in different layer spaces with corresponding rail.

17. The storage apparatus for automatic material handling system of claim 11, wherein at least one of the hanging spaces stores multiple hangers stacking on top of each other.

18. The storage apparatus for automatic material handling system of claim 11, further comprises a crane module, disposed under the suspension brackets and facing toward one of the hanging spaces, a front opening unified pod (FOUP) is carried by the crane module to be delivered and secured to the hanger, wherein the crane module has three-axis movement dimensions.

19. The storage apparatus for automatic material handling system of claim 11, wherein the hanger has a lateral opening and a bottom slot, three positioning pins of the hanger are located on a protrusion of the hanger along the bottom slot, a top flange of the FOUP moves in or out of a receiving space of the hanger by passing through the lateral opening, and a neck portion of the FOUP moves in or out of the bottom slot along with the top flange moving, wherein the neck portion is connected between a pod body and the top flange of the FOUP.

20. The storage apparatus for automatic material handling system of claim 19, wherein the lateral opening is the only one entrance or exit for the top flange moving in or out of the receiving space.

21. The storage apparatus for automatic material handling system of claim 19, wherein a width of the bottom slot is smaller than a width of the top flange.
